(19) United States
(12) Patent Application Publication
(10) Pub. No.: US 2008/0124914 A1
(43) Pub. Date: May 29, 2008

(54) METHOD OF FABRICATING FLASH MEMORY DEVICE

(75) Inventor: Myung Kyu AHN, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/771,935

(22) Filed: Jun. 29, 2007

(30) Foreign Application Priority Data
Jul. 5, 2006 (KR) 2006-63144

(51) Int. Cl. H01L 21/4763

(52) U.S. Cl. 438/637; 257/E21.495

(57) ABSTRACT

A method of fabricating a flash memory device includes forming an insulating layer and a hard mask film pattern over a semiconductor substrate. A spacer is formed along surfaces of the hard mask film pattern and the insulating layer. Contact holes are formed in the insulating layer by a first etch process using the hard mask pattern and the spacer as etch masks. The spacer is removed during the first etch process. A second etch process is performed to remove the hard mask film pattern.

### CROSS-REFERENCES TO RELATED APPLICATIONS

The present application claims priority to Korean patent application number 2006-63144, filed on Jul. 5, 2006, which is incorporated by reference in its entirety.

### BACKGROUND OF THE INVENTION

The present invention relates, in general, to a flash memory device and, more particularly, to a method of fabricating a flash memory device having an improved contact hole profile.

As the size of a flash memory device reduces to less than 70 nm, an etch margin shortage phenomenon frequently results. In a drain contact process, nitride is used as a hard mask film instead of polysilicon. Nitride solves the etch margin shortage problem of a photoresist in a lithography process when using an ArF laser as a light source.

If a contact hole is formed using a nitride hard mask film, however, the size of the contact hole is increased by 20 nm or more compared to forming the contact hole using a polysilicon hard mask film. Not only is the space between neighboring contact holes decreased, but also a bride problem may result due to a bowing phenomenon at a central portion of the contact hole.

### SUMMARY OF THE INVENTION

Accordingly, the present invention addresses the above problems, and discloses a method of fabricating a flash memory device, which stably reduces the size of a contact hole. The method overcomes the limitation of a lithography process that requires a reduction in the size of the contact hole and a reduction in the space between the contact holes as the design rule decreases.

According to an aspect of the present invention, a method of fabricating a flash memory device includes forming an insulating layer and a hard mask film pattern over a semiconductor substrate. A spacer is formed along surfaces of the hard mask film pattern and the insulating layer. Contact holes are formed in the insulating layer by a first etch process using the hard mask pattern and the spacer as etch masks. The spacer is removed during the first etch process. A second etch process is performed to remove the hard mask film pattern.

### BRIEF DESCRIPTION OF THE DRAWINGS

FIGS. 1 to 5 are cross-sectional views illustrating a method of fabricating a flash memory device according to an embodiment of the present invention.

### DESCRIPTION OF SPECIFIC EMBODIMENTS

A specific embodiment according to the present invention will be described with reference to the accompanying drawings.

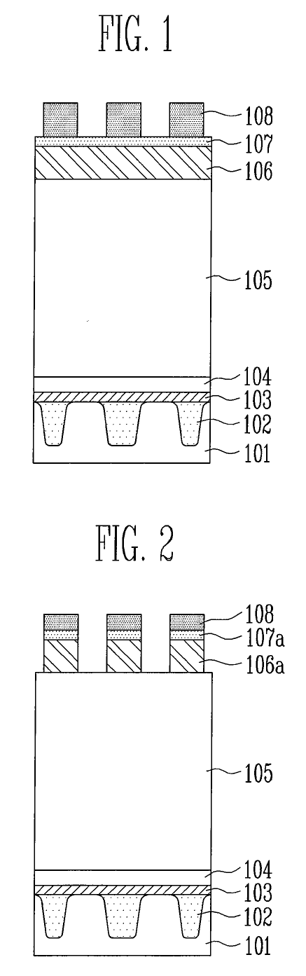

FIGS. 1 to 5 are cross-sectional views illustrating a method of fabricating a flash memory device according to an embodiment of the present invention.

Referring to FIG. 1, a series of films for a contact formation process are formed over a semiconductor substrate 101 in which isolation films 102 are formed. The series of films include a buffer insulating film, 103, an etch-stop insulating film 104, an insulating layer 105 and a hard mask film 106. An anti-diffused reflection film 107 and a photoresist pattern 108 are formed over the hard mask film 106.

The buffer insulating film 103 is formed of oxide-based material, the etch-stop insulating film 104 is formed of nitride-based material, the insulating layer 105 is formed of oxide-based material, the hard mask film 106 is formed of nitride-based material, and the anti-diffused reflection film 107 is formed of Organic Bottom Anti-Reflective Coating (OBARC) material. The photoresist pattern 108 is formed by a lithography process that requires a reduction in the size of a contact hole and/or a reduction in the space between contact holes as the design rule decreases. Portions of the photoresist pattern 108 are arranged to form an etch mask to assist in the formation of the contact holes.

Referring to FIG. 2, the anti-diffused reflection film 107 and the hard mask film 106 are etched by an etch process using the photoresist pattern 108 as an etch mask. The resulting structure includes an anti-diffused reflection film pattern 107a and a hard mask film pattern 106a.

Referring to FIG. 3, the photoresist pattern 108 and the anti-diffused reflection film pattern 107a are removed. A spacer film 109 for a hard mask is formed along the surfaces of the hard mask film pattern 106a and the insulating layer 105.

The spacer film 109 is formed from oxide, oxynitride or nitride-based material by a Chemical Vapor Deposition (CVD) or a sputtering method. The spacer film 109 may be formed to a thickness of 10 angstroms or more in the case of a 70 nm flash memory device. Preferably, the spacer film 109 is formed such that the space between the hard mask film patterns 106a is not entirely filled. The thickness of the spacer film 109 can be controlled according to the design rule of a device.

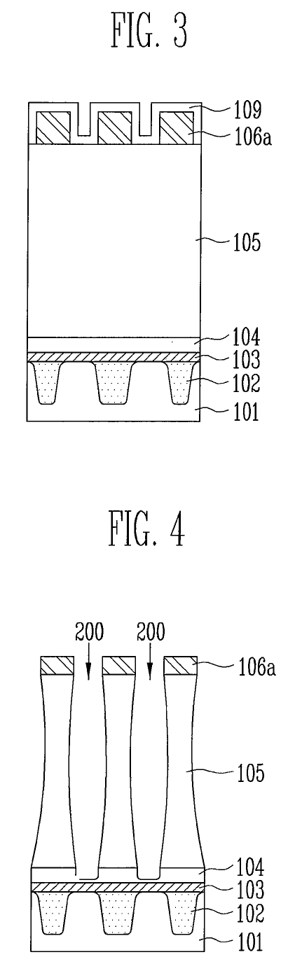

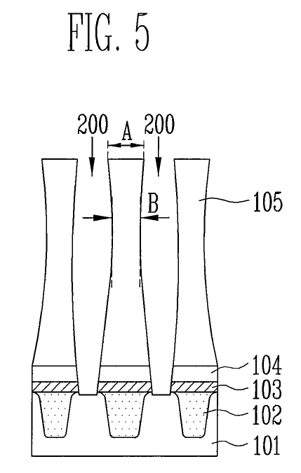

Referring to FIG. 4, after the spacer film 109 is formed on the hard mask film pattern 106a, an etch process is performed to form contact holes 200 in the insulating layer 105. The spacer film 109 is removed by the etch process. In the event that a portion of the spacer film 109 remains on the hard mask film pattern 106a, the spacer film 109 may be removed by a subsequent process of removing the hard mask film pattern 106a.

During the etch process of forming the contact hole 200, if the etch thickness of the insulating layer 105 is too large, the size of the contact hole 200 may increase due to lateral etching. In order to minimize the effect of lateral etching, the etch process may be performed by reducing pressure, decreasing maximum power, reducing a cathode temperature, or a combination thereof. In addition, a large thickness of the insulating layer 105 may result in a bowing phenomenon in which the width of the contact hole 200 at a central portion of the contact hole 200 is abnormally increased. In order to minimize the bowing phenomenon, the etch process can be performed by decreasing the flow rate of O₂. In one embodiment, the etch process can be performed at a pressure of approximately 10 to 100 mTorr, a cathode temperature of approximately −20 to 20 degrees, a power of approximately 500 to 1500 W, and a flow rate of O₂ of approximately 5 to 100 sccm.

The etch process can be performed in an in-situ manner by consecutively etching the spacer film 109 and the insulating layer 105 while maintaining the spacer film 109 and the insulating layer 105 at a vacuum state within the same etch equipment. Alternatively, the etch process can be performed in an ex-situ manner by etching the spacer film 109 and the insulating layer 105 discontinuously using different etch equipment.

As described above, the spacer film 109 is formed on the hard mask film 106 and the etch process is performed such that lateral etching is minimized. Accordingly, the overall size of the contact hole 200 can be prevented from increasing, and the bowing phenomenon (in which the width of the contact hole 200 at a central portion thereof is abnormally increased) can be minimized.

Referring to FIG. 5, the hard mask film pattern 106a, the etch-stop insulating film 104 and the buffer insulating film 103 are removed to form the contact hole 200 through which the semiconductor substrate 101 is exposed.

The removal process can be performed by removing the hard mask film pattern 106a, and then removing the etch-stop insulating film 104 and the buffer insulating film 103. If the hard mask film pattern 106a, the etch-stop insulating film 104 and the buffer insulating film 103 are removed at the same time, the semiconductor substrate 101 may be damaged during the removal process when the hard mask film pattern 106a is too thick. However, since a specific thickness of the hard mask film pattern 106a has been removed during the previous etch process, etch damage to the semiconductor substrate 101 is negligible.

In order to minimize lateral etching of the contact hole 200, the removal process can be performed by using a mixture of CF₄ gas and CHF₃, CH₂F₂ or CH₃F. In one embodiment, the flow rate of CHF₃, CH₂F₂ or CH₃F relative to the CF₄ gas can be controlled in a range of 10 to 90% so that the selectivity of nitride to oxide is 1.4 or greater.

The contact hole 200 formed by the process described above in accordance with the present invention has a stabilized target size. Accordingly, space margin A between the contact holes 200 near an upper portion of the contact hole 200 can be sufficiently secured. Furthermore, space margin B near a central portion of the contact hole 200, in which the bowing phenomenon may be generated, can be secured such that the bridge problem is not an issue.

As described above, according to the present invention, the size of the contact hole can be reduced in a stable manner while overcoming the limitation of a lithography process that requires a reduction in the size of the contact hole and a reduction in the space between the contact holes as the design rule decreases. Accordingly, the bridge problem can be solved fundamentally and the reliability of a device can be improved.

Although the foregoing description has been made with reference to a specific embodiment, it is to be understood that changes and modifications to the present invention may be made by one ordinary skilled in the art without departing from the spirit and scope of the present invention and the appended claims.

What is claimed is:

1. A method of fabricating a flash memory device, the method comprising:
forming an insulating layer and a hard mask film pattern over a semiconductor substrate;
forming a spacer along surfaces of the hard mask film pattern and the insulating layer;
forming contact holes in the insulating layer by performing a first etch process using the hard mask pattern and the spacer as etch masks, wherein the spacer is removed during the first etch process; and
performing a second etch process to remove the hard mask film pattern.

2. The method of claim 1, further comprising forming an etch-stop insulating film below the insulating layer.

3. The method of claim 2, wherein a buffer insulating film is formed below the etch-stop insulating film.

4. The method of claim 3, further comprising etching the etch-stop insulating film and the buffer insulating film under the contact hole after the second etch process is performed.

5. The method of claim 3, wherein performing the second etch process further comprises etching the hard mask film pattern, the etch-stop insulating film and the buffer insulating film.

6. The method of claim 1, wherein the hard mask film pattern is formed from nitride-based material.

7. The method of claim 1, wherein the spacer is formed from oxide, oxynitride or nitride-based material.

8. The method of claim 1, wherein the first etch process is performed under conditions of reduced pressure, decreased maximum power, reduced cathode temperature, or a combination thereof.

9. The method of claim 1, wherein the first etch process is performed at a pressure of approximately 10 to 100 mTorr, a cathode temperature of approximately −20 to 20 degrees, a power of approximately 500 to 1500 W.

10. The method of claim 1, wherein the first etch process is performed under a condition of a decreased a flow rate of O₂.

11. The method of claim 1, wherein the first etch process is performed at flow rate of O₂ of approximately 5 to 100 sccm.

12. The method of claim 1, wherein the first etch process is performed in an in-situ manner by consecutively etching the spacer film and the insulating layer while maintaining the spacer film and the insulating layer at a vacuum state within the same etch equipment.

13. The method of claim 1, wherein the first etch process is performed in an ex-situ manner by etching the spacer film and the insulating layer discontinuously using different etch equipment.

14. The method of claim 1, wherein the second etch process is performed by using a mixture of a CF₄ gas and at least one of CHF₃, CH₂F₂ or CH₃F.

15. The method of claim 14, wherein a flow rate of the CHF₃, CH₂F₂ or CH₃F relative to the CF₄ gas is approximately 10 to 90%.
